(19) United States
(12) Patent Application Publication
(10) Pub. No.: US 2026/0231783 A1
(43) Pub. Date: Aug. 6, 2026

(54) PACKAGE-INTEGRATED LEAD FRAME ANTENNAS

(71) Applicant: TEXAS INSTRUMENTS INCORPORATED, Dallas, TX (US)

(72) Inventors: Hassan Omar ALI, Murphy, TX (US); Brian P. GINSBURG, Allen, TX (US); Juan HERBSOMMER, Allen, TX (US); Satyendra S. CHAUHAN, Murphy, TX (US)

(21) Appl. No.: 19/043,327

(22) Filed: Jan. 31, 2025

(51) Int. Cl. H10W 70/40; H10W 44/20; H10W 72/00; H10W 72/50; H10W 74/01; H10W 74/10; H10W 90/00

(52) U.S. Cl. CPC H10W 70/429; H10W 44/20; H10W 70/411; H10W 44/206; H10W 44/248; H10W 72/0198; H10W 72/536; H10W 72/5363; H10W 72/5445; H10W 74/016; H10W 74/10; H10W 90/756; H10W 90/758

(57) ABSTRACT

In examples, a semiconductor package includes a portion of a lead frame including a die pad, a package pin, and an antenna having first and second segments, with at least one of the first and second segments having a meandering portion. The package includes a semiconductor die coupled to the die pad and having a device side in which circuitry is formed, a first bond wire coupling the device side to the package pin, a second bond wire coupling the first segment to the second segment, and a third bond wire coupling the device side to the antenna. The package includes a mold compound covering the semiconductor die, at least part of the package pin, the antenna, and the first, second, and third bond wires. Portions of the first and second segments are exposed on multiple exterior lateral surfaces of the mold compound.

### BACKGROUND

Semiconductor wafers are circular pieces of semiconductor material, such as silicon, that are used to manufacture semiconductor chips. Generally, complex manufacturing processes are used to form numerous integrated circuits on a single wafer. The formation of such circuits on a wafer is called fabrication. After wafer fabrication, the wafer is cut into multiple pieces, called semiconductor dies, with each die containing one of the circuits. The cutting, or sawing, of the wafer into individual dies is called singulation. An individual die may then be coupled to a substrate or die pad. The resulting structure may be subsequently covered with a mold compound to produce a package.

### SUMMARY

In examples, a semiconductor package includes a portion of a lead frame including a die pad, a package pin, and an antenna having first and second segments, with at least one of the first and second segments having a meandering portion. The package includes a semiconductor die coupled to the die pad and having a device side in which circuitry is formed, a first bond wire coupling the device side to the package pin, a second bond wire coupling the first segment to the second segment, and a third bond wire coupling the device side to the antenna. The package includes a mold compound covering the semiconductor die, at least part of the package pin, the antenna, and the first, second, and third bond wires. Portions of the first and second segments are exposed on multiple exterior lateral surfaces of the mold compound.

In examples, a method for manufacturing a semiconductor package includes coupling a first semiconductor die to a first die pad of a lead frame, the lead frame further comprising a second die pad, first and second package pins, and first and second antennas. The first and second antennas are coupled directly to each other without a tie bar in between the first and second antennas. Each of the first and second antennas includes multiple linear segments coupled in series at approximately right angles. The method also includes coupling a second semiconductor die to the second die pad, wirebonding the first semiconductor die to the first package pin and the first antenna, and wirebonding the second semiconductor die to the second package pin and the second antenna. The method includes covering the first and second semiconductor dies, the first and second die pads, and the first and second antennas with a mold compound. The method includes cutting the mold compound and the lead frame in between the first and second antennas to produce the semiconductor package.

### BRIEF DESCRIPTION OF THE DRAWINGS

FIG. 1 is a block diagram of an electronic device including a semiconductor package having a lead frame antenna, in accordance with various examples.

FIGS. 2A, 2B, 2C, 2D are top-down, perspective, profile, and profile views of a semiconductor package having a lead frame antenna, in accordance with various examples.

FIG. 3 is a flow diagram of a method for manufacturing a semiconductor package having a lead frame antenna, in accordance with various examples.

FIGS. 4A1,4A2, 4A3, 4B1, 4B2, 4B3, 4C1, 4C2, 4C3, 4D1, 4D2, and 4D3 are a process flow of a method for manufacturing a semiconductor package having a lead frame antenna, in accordance with various examples.

FIGS. 5, 6, and 7 are graphs depicting the performance of a semiconductor package having a lead frame antenna, in accordance with various examples.

FIG. 8 is a schematic diagram depicting the radiation pattern of a semiconductor package having a lead frame antenna, in accordance with various examples.

FIGS. 9A, 9B, 9C, and 9D are top-down, perspective, profile, and profile views of a semiconductor package including a lead frame antenna, in accordance with various examples.

FIGS. 10, 11, and 12 are graphs depicting the performance of a semiconductor package having a lead frame antenna, in accordance with various examples.

FIG. 13 is a schematic diagram depicting the radiation pattern of a semiconductor package having a lead frame antenna, in accordance with various examples.

FIGS. 14A, 14B, 14C, and 14D are top-down, perspective, profile, and profile views of a semiconductor package having a lead frame antenna, in accordance with various examples.

### DETAILED DESCRIPTION

Different package types are suited to various applications and budgetary constraints, with some specifically designed to support wireless technologies. High-frequency wireless communications, such as 2.4 GHz Bluetooth and Wi-Fi, use antennas of a precise length (e.g., one-quarter wavelength) for efficient operation. Low-cost packages like small outline transistor (SOT) and small outline integrated circuit (SOIC) packages lack the physical space to integrate these relatively long antennas. Consequently, in such applications, antennas are placed externally to the package, such as on a printed circuit board (PCB).

While positioning antennas on PCBs enables the use of small, low-cost packages, but also consumes valuable PCB area, increasing cost and reducing opportunities for system miniaturization. Additionally, circuits driving PCB antennas often interface through large package leads, which can introduce impedance parasitics due to the large lead size. These parasitics degrade the performance of wireless communication, posing further challenges for integrating high-frequency functionality in compact and economical packages (e.g., SOT packages).

This description presents various examples of small, low-cost packages that integrate high-frequency antennas, thus mitigating the technical challenges described above. More specifically, the packages described herein include meander line antennas (MLAs). An MLA is a compact antenna design in which the metallic radiating element has a serpentine or zigzag pattern to increase the electrical length of the radiating element within a limited physical space. The MLA is part of the lead frame used to manufacture a semiconductor package. Other components of the package, such as the package leads (also referred to herein as package pins), are also part of the same lead frame as the MLA. In examples, a semiconductor package includes a semiconductor die having a device side in which circuitry is formed and a package pin extending away from the semiconductor die. The package also includes an MLA having first and second segments, and a gap present between the first and second segments. The package includes a first bond wire coupling the device side of the semiconductor die to the package pin. The package also includes a second bond wire extending across the gap and coupling the first segment to the second segment. The package includes a mold compound covering the semiconductor die, at least part of the package pin, the meander line antenna, and the first and second bond wires. The first and second segments are exposed on multiple exterior lateral surfaces of the mold compound. The lead frame MLA provides an inexpensive and convenient way to equip low-cost semiconductor packages with high-frequency, high-performance antennas suitable for use in gigahertz-range wireless applications. Further, by including the high-frequency antenna within the semiconductor package, the antenna is not included on the PCB, thus mitigating the technical disadvantages associated with PCB antennas (e.g., the parasitics described above).

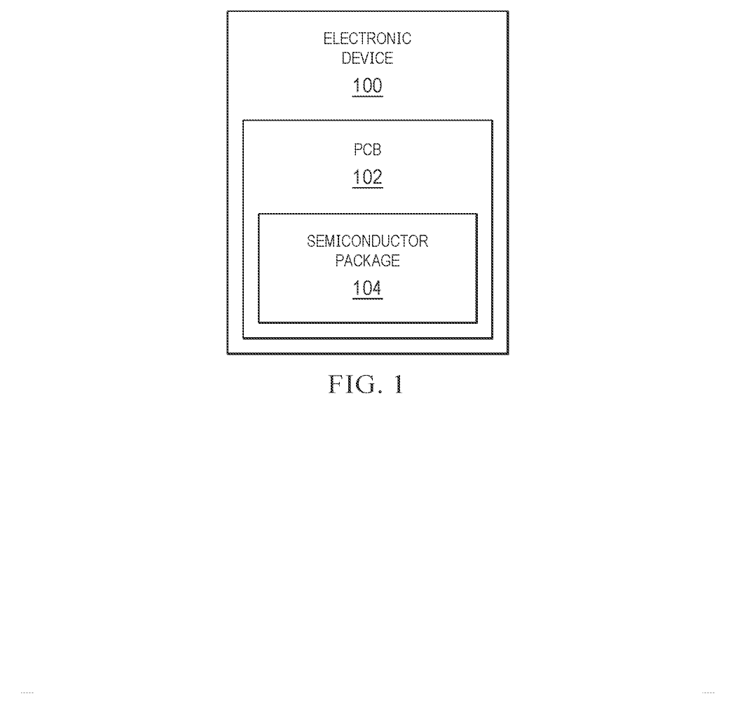

FIG. 1 is a block diagram of an electronic device including a semiconductor package having a lead frame antenna, in accordance with various examples. In particular, FIG. 1 depicts an electronic device 100 including a printed circuit board (PCB) 102 and a semiconductor package 104 coupled to the PCB 102. A high-frequency (e.g., 2.4 GHz), high-performance antenna may be included inside the semiconductor package 104 and may form a portion of a lead frame used to manufacture the semiconductor package 104. For example, the antenna may have been part of the same lead frame from which the die pad and the package pins of the semiconductor package 104 were obtained. Thus, the high-frequency, high-performance antenna is inexpensive, efficient, and simple to incorporate into the semiconductor package 104, including small and inexpensive packages such as small outline transistor (SOT), small outline integrated circuit (SOIC), and dual flat no lead (DFN) packages. Examples of the electronic device 100 include an automobile, an aircraft, a watercraft, a spacecraft, a video game console, a smartphone, an entertainment device, a stereo system, an appliance, a laptop computer, a desktop computer, a tablet, a notebook, or any other suitable type of electronic device or system.

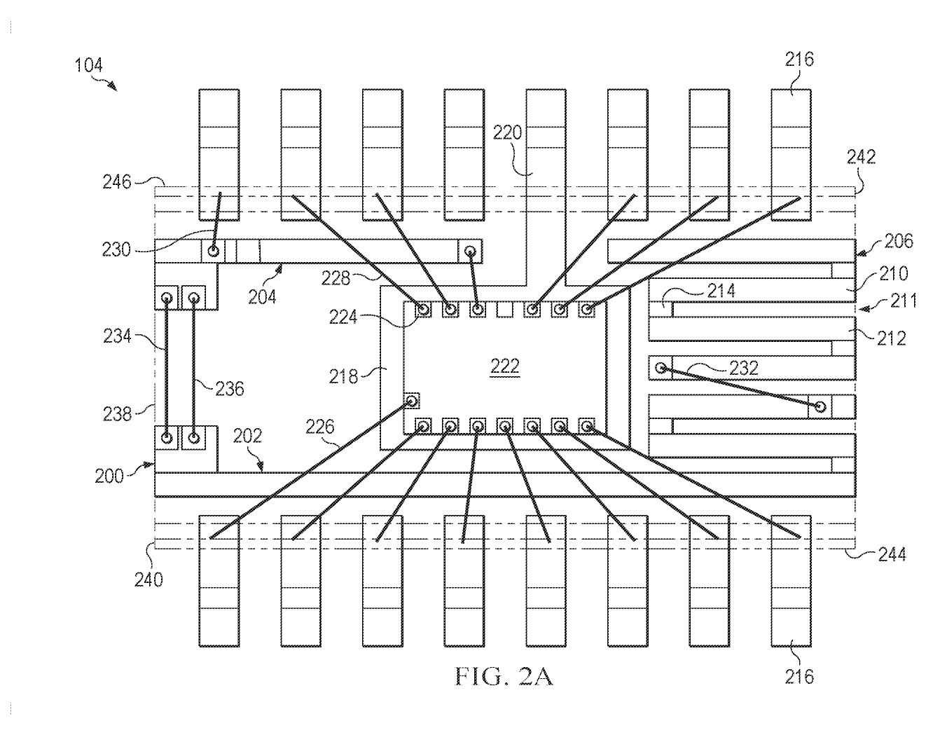

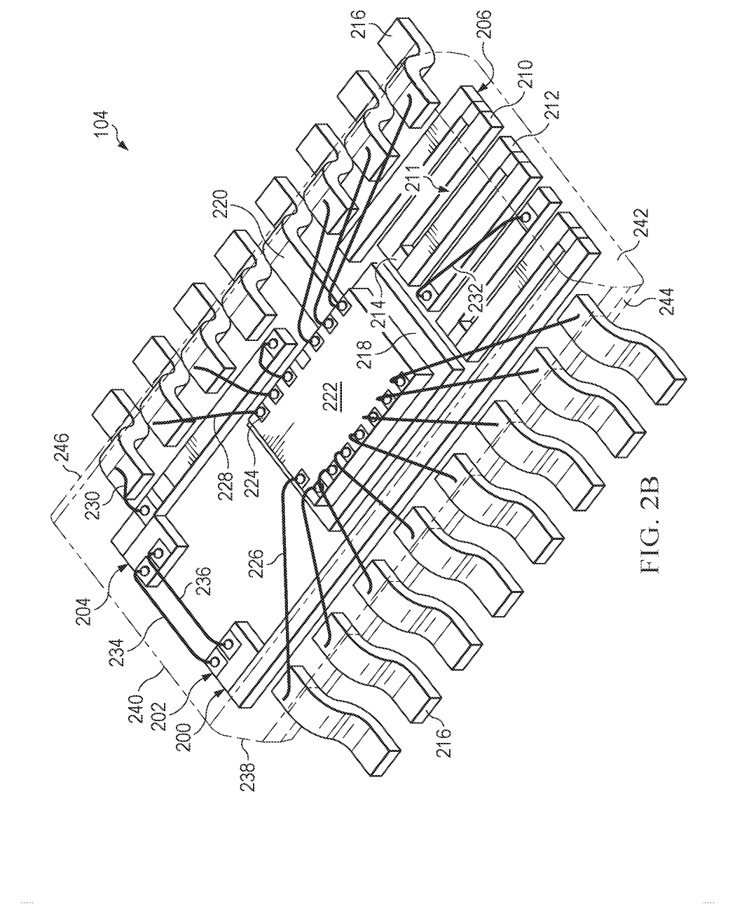

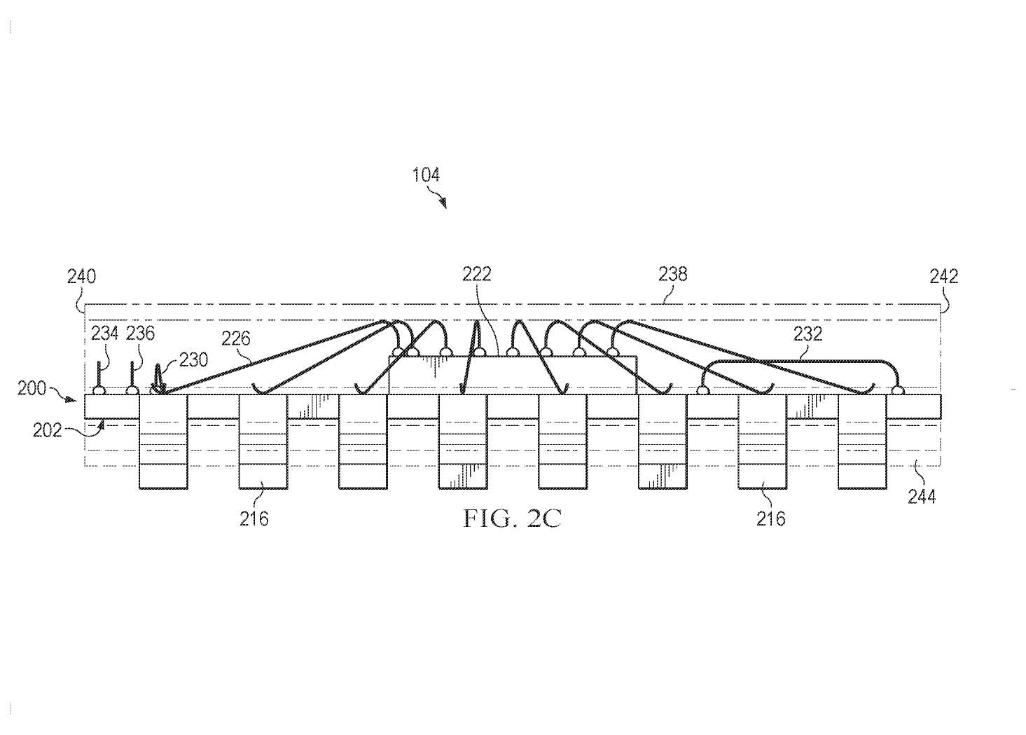

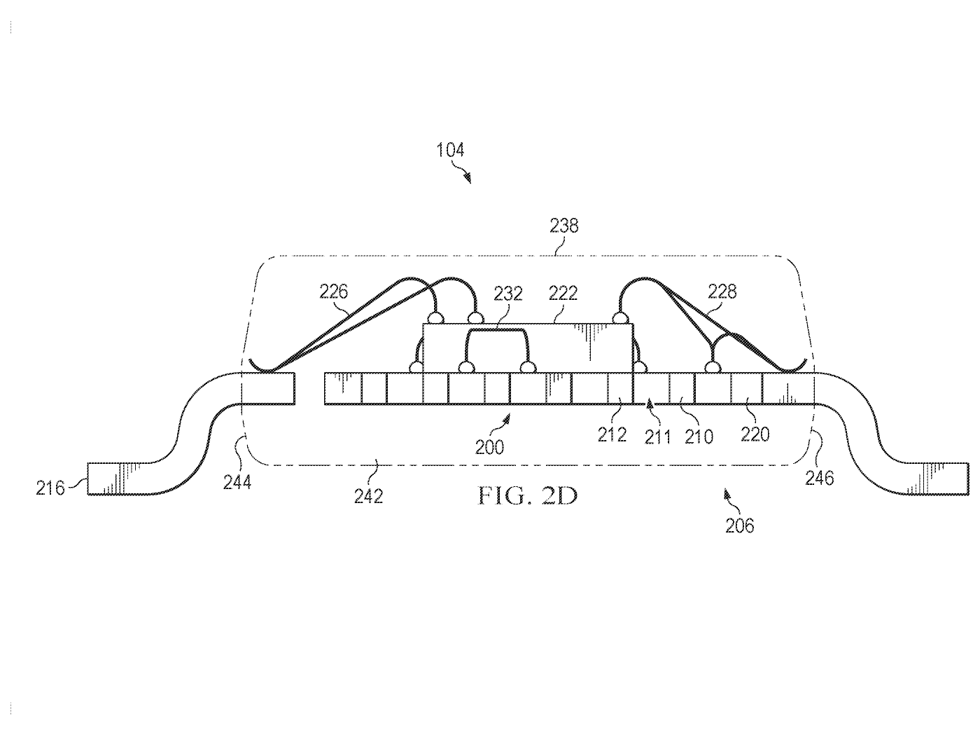

FIGS. 2A, 2B, 2C, and 2D are top-down, perspective, profile, and profile views of a semiconductor package having a lead frame antenna, in accordance with various examples. Specifically, FIGS. 2A-2D depict various views of an example semiconductor package 104, such as the semiconductor package 104 depicted in FIG. 1. The example semiconductor package 104 includes a portion of a lead frame that includes an antenna 200. The antenna 200 includes segments 202, 204, and 206. The segments 202, 204, and 206, do not directly contact each other, as shown. The segments 202, 204, and 206 may comprise copper or any other metal or metal alloy of which a lead frame (and, post-trimming, a portion of a lead frame) is fabricated. One or more of the segments 202, 204, and 206 may include a meandering portion. A meandering portion is defined as a segment portion that includes multiple, linear sub-segments linked in series at approximately right angles, where each of the multiple, linear sub-segments is at least partially separated from another one of the multiple, linear sub-segments by a non-metallic region. For example, a sub-segment 210 and a sub-segment 212 extend approximately parallel to each other and are coupled to each other by a sub-segment 214. The sub-segments 210, 212, and 214 are linked in series at approximately right angles, as shown. A non-metallic region 211 (e.g., filled with a mold compound 238) separates the sub-segments 210 and 212 from each other.

The antenna 200 may be referred to as a meander line antenna. A meander line antenna is a linear antenna folded into a compact pattern with sub-segments linked in series at right angles as described above, effectively increasing the electrical length of the antenna to achieve resonance at lower frequencies while minimizing physical size. This structure leverages the principle of inductive and capacitive loading to achieve high performance in a confined space. The dimensions (e.g., length, width, thickness) of a meander line antenna, such as the antenna 200, may be selected to achieve a particular frequency of operation (e.g., 2.4 GHz), a specific current-carrying capacity, and impedance matching, and to comply with one or more manufacturing constraints.

The specific structures of example antennas 200 may vary. For example, the dimensions of the antenna 200, the number of segments, sub-segments, and/or right angles in the antenna 200, the specific layout of the segments and/or sub-segments of the antenna 200, distances between sub-segments that are filled with non-metallic material such as mold compound, etc., may be varied as desired and as described above. Covering antenna segments with a material such as the mold compound that has higher permittivity than air further helps in antenna miniaturization.

In some examples, the antenna 200 includes one continuous, unbroken segment. In other examples, such as that shown in FIGS. 2A-2D, the antenna 200 includes multiple segments 202, 204, and 206. These segments may be coupled to each other by bond wires. For example, a bond wire 232 may couple the segments 202 and 206 together. Similarly, bond wires 234 and 236 may couple the segments 202 and 204 to each other. Such bond wires may be useful for various purposes. For example, bond wires provide a small and controllable inductance due to their length and loop area, which can be useful to fine-tune the impedance resonant frequency, and matching performance of the antenna 200. The relationship between the bond wire length, frequency, and inductance may vary and can be application-specific. For example, longer bond wires may result in increased inductance and lowered resonant frequency. Further, bond wires coupled in parallel, such as the bond wires 234 and 236, reduce total resistance because the effective resistance of parallel bond wires is less than that of a single bond wire, which helps maintain the antenna’s target impedance and improves performance at high frequencies (e.g., 2.4 GHz) where bond wire loss becomes significant. Such parallel bond wires also reduce parasitics and can carry additional current compared to a single bond wire. For further antenna impedance tuning, a short circuit stub can be implemented through bond wire 230 coupling the antenna 200 to one or more of the grounded package pins 216, which may be of any suitable type (e.g., gullwing pins). In some examples, a rigid copper connection is used in lieu of the bond wire 230. For example, the antenna 200 and one or more of the package pins 216 may be part of a lead frame used to manufacture the semiconductor package 104, and thus the antenna 200 and the one or more package pins 216 may form a monolithic whole, with no fusion or coupling of the antenna 200 and the one or more package pins 216. For instance, the bond wire 230 can be replaced with a rigid copper connection, which can facilitate the formation of an inverted-F antenna, which includes a grounded element (i.e., through a grounded package pin 216) and a radiating element for impedance matching.

The semiconductor package 104 includes a die pad 218, a tie bar 220 extending from the die pad 218, and a semiconductor die 222 coupled to the die pad 218. The semiconductor die 222 includes a device side in which circuitry is formed, and which faces away from the die pad 218. A top surface of the die pad 218 is coplanar with top surfaces of the segments 202, 204, 206. The device side of the semiconductor die 222 includes one or more bond pads 224. Such bond pads 224 may be used to facilitate coupling of bond wires to surfaces throughout the semiconductor package 104. Bond wires 226 couple the bond pads 224 on the device side of the semiconductor die 222 to the package pins 216. A bond wire 228 couples a bond pad 224 on the device side of the semiconductor die 222 to the antenna 200, through which the semiconductor die 222 may send signals to and/or receive signals from the antenna 200.

A mold compound 238 covers the various structures of the semiconductor package 104 described above. The mold compound 238 includes external lateral surfaces 240, 242, 244, and 246. The surfaces 240 and 242 oppose each other, and the surfaces 244 and 246 oppose each other. The surfaces 240 and 242 are perpendicular to the surfaces 244 and 246 and vice versa. The surface area of each of the surfaces 240 and 242 is smaller than the surface area of each of the surfaces 244 and 246. The package pins 216 extend through the surfaces 244 and 246, as shown. The antenna 200 is exposed to the surfaces 240 and 242, as shown. The antenna 200 may be exposed to the surfaces 240 and 242 because the antenna 200 is part of the lead frame that was used to manufacture the semiconductor package 104, and the lead frame is connected to other lead frames in series format on a lead frame strip. Thus, prior to manufacture of the semiconductor package 104, the lead frame that included the antenna 200 was coupled to one or more other lead frames that also included respective antennas 200, and these antennas were directly coupled to each other without the use of tie bars or other intervening materials. During manufacture, each of these lead frames is incorporated into a different semiconductor package 104, and after the mold compound 238 is applied, the packages are singulated from each other (e.g., by mechanical saw), resulting in semiconductor packages 104 in which the antennas 200 are exposed to the external lateral surfaces 240 and 242, as shown. The tie bar 220 may be exposed to the external surface 246 as a result of trimming the tie bar 220 during manufacture.

In operation, the semiconductor die 222 drives the antenna 200 to transmit wireless signals from the semiconductor package 104. Similarly, the semiconductor die 222 receives signals from the antenna 200 that were received from other devices outside the semiconductor package 104.

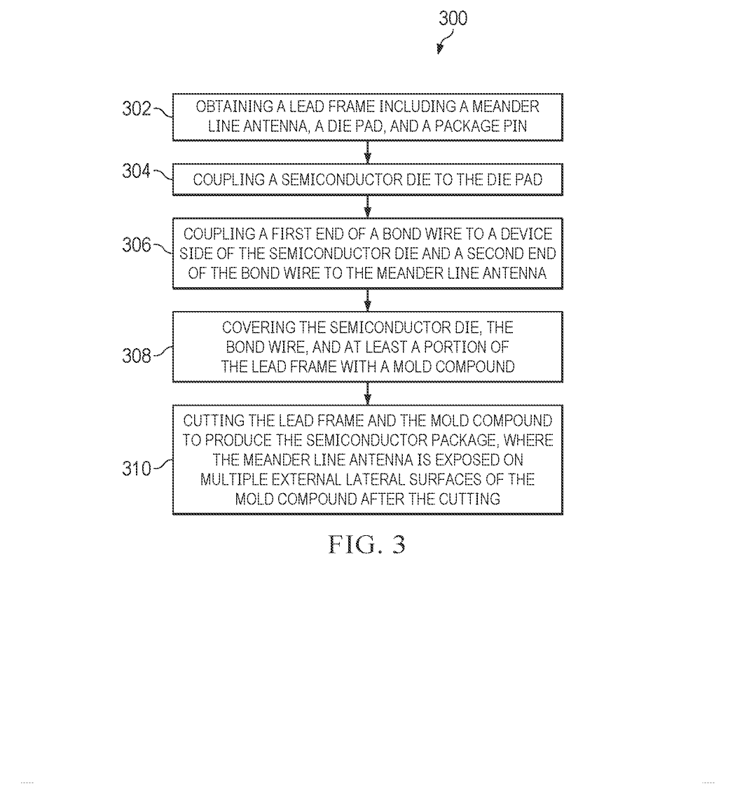

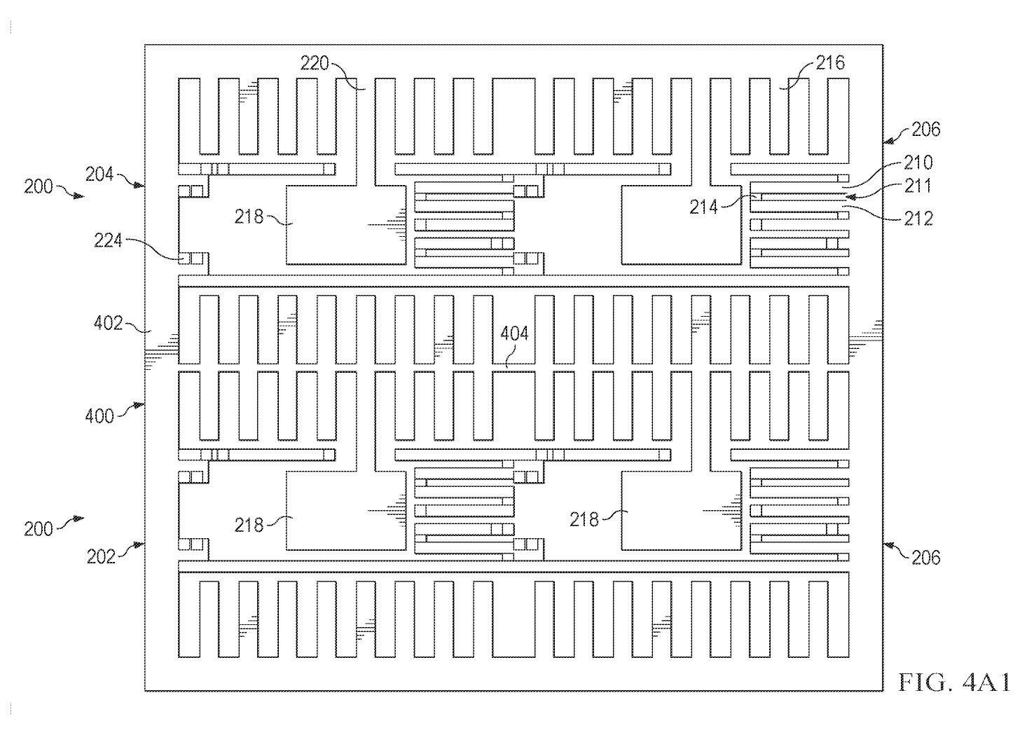

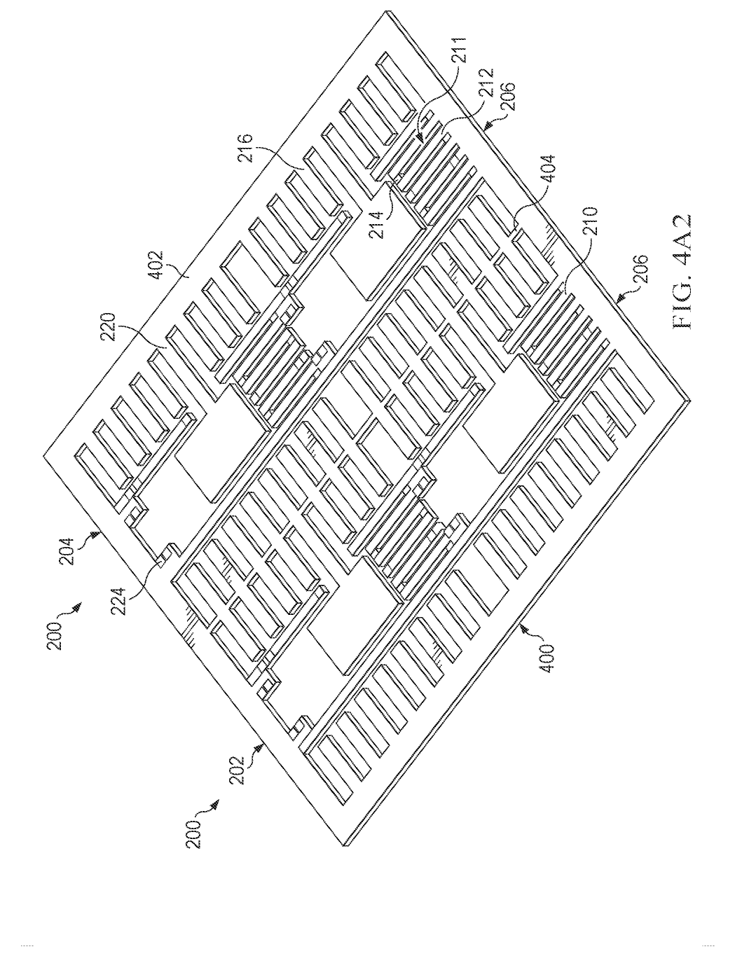

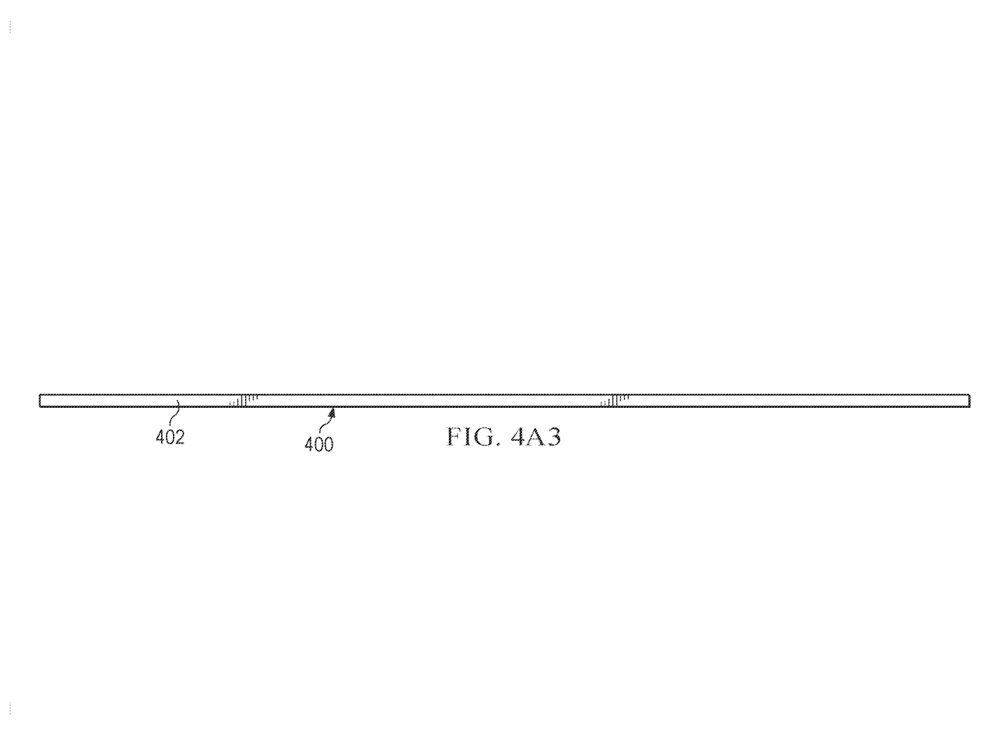

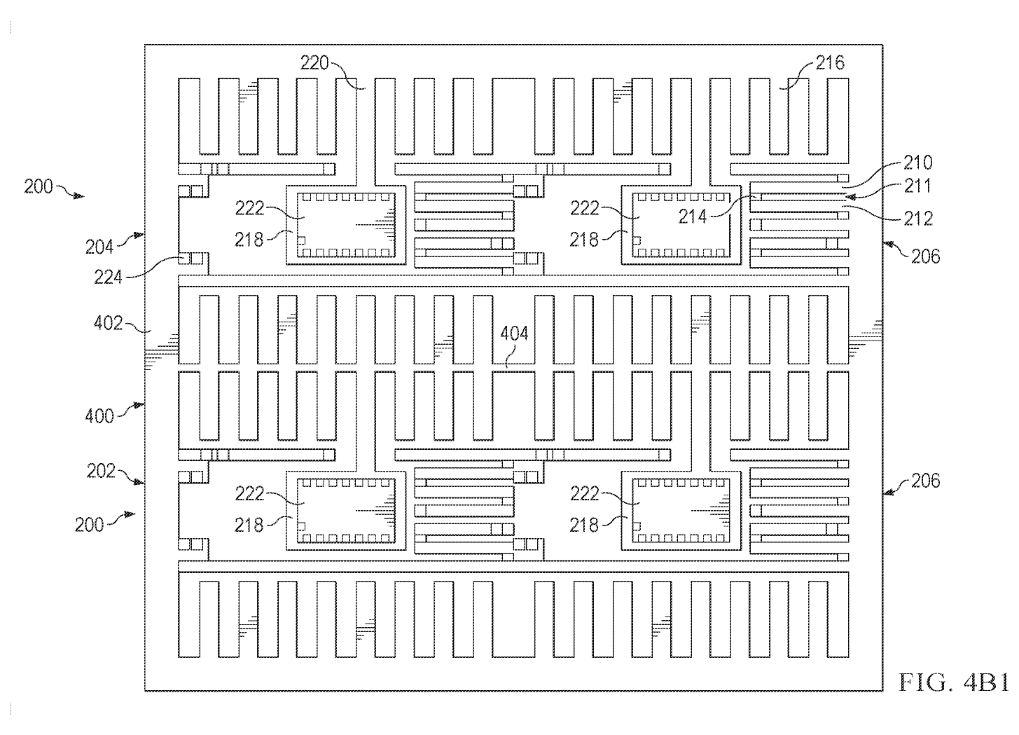

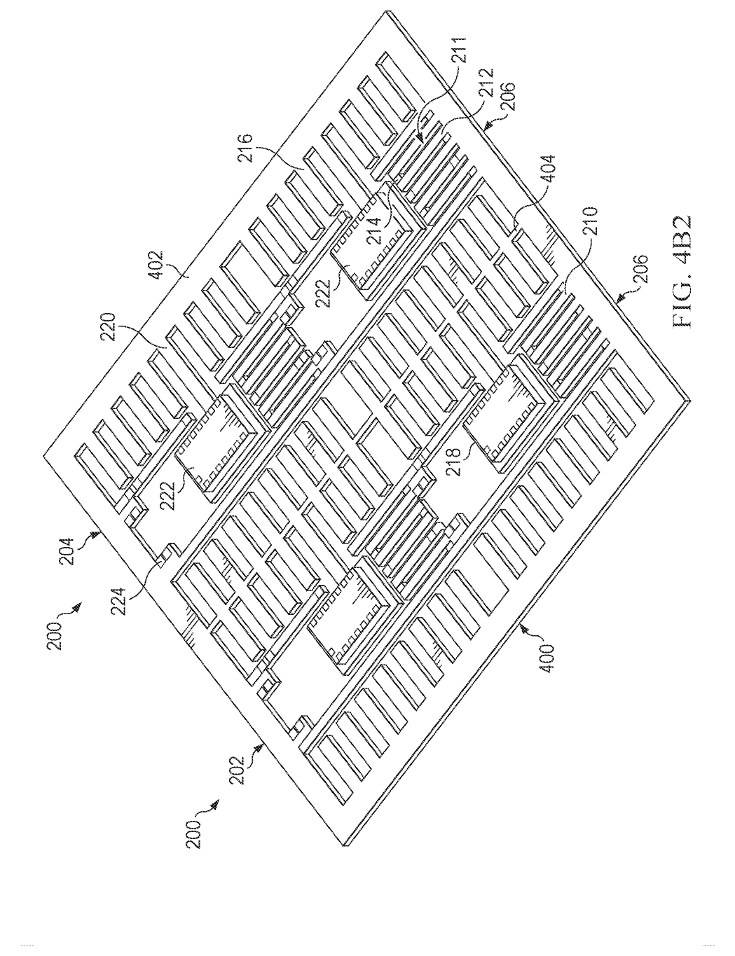

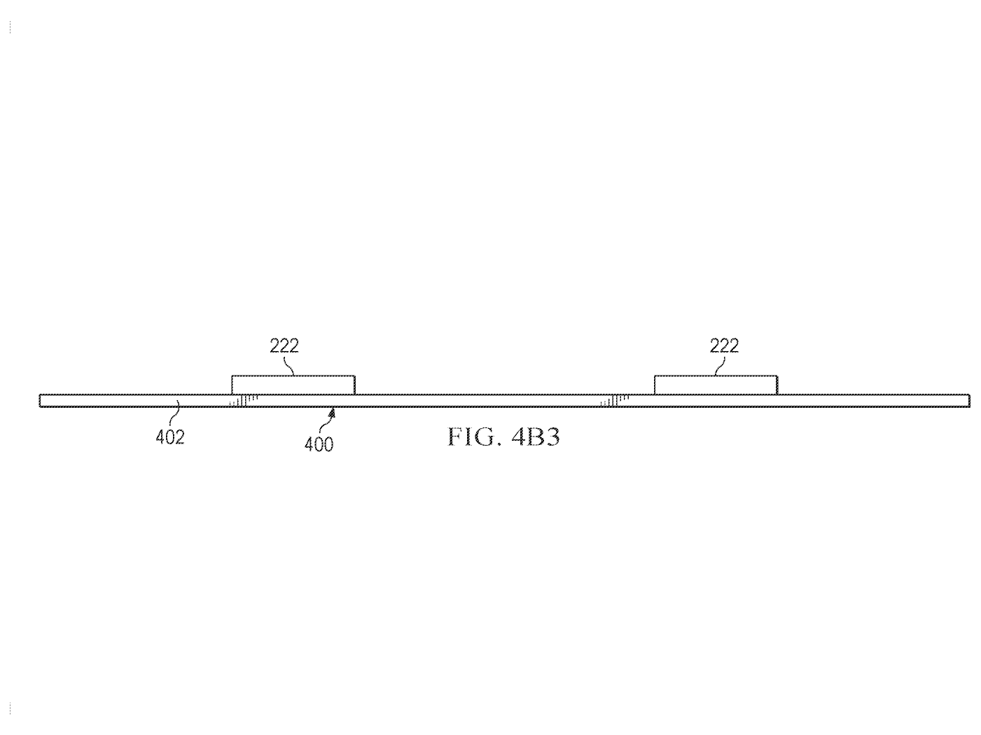

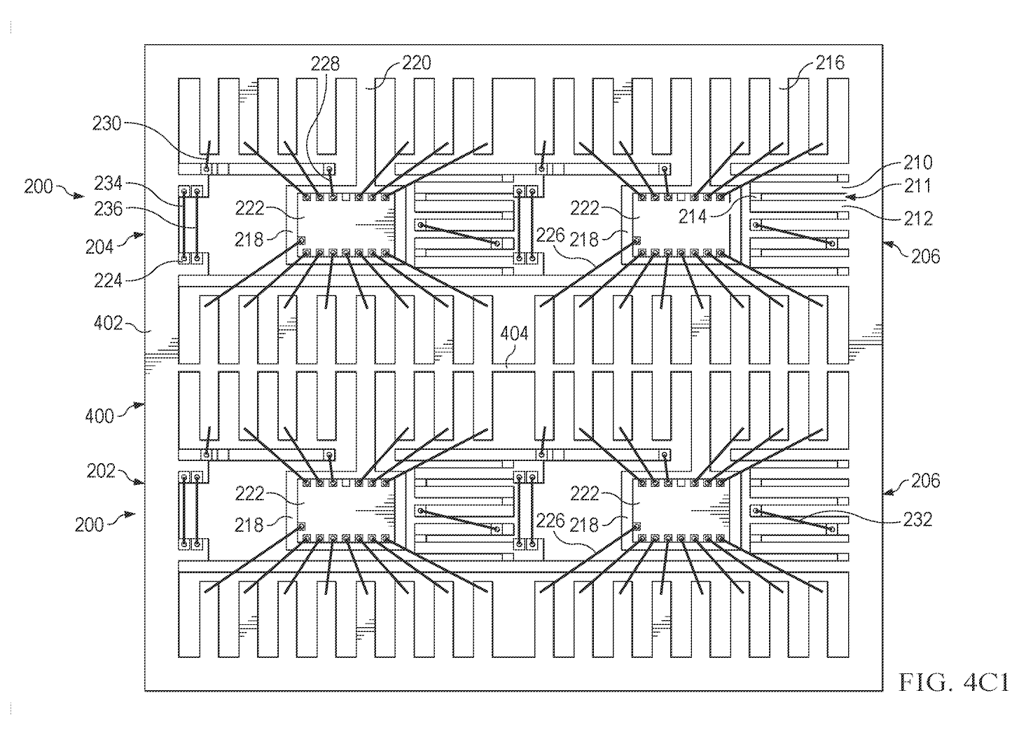

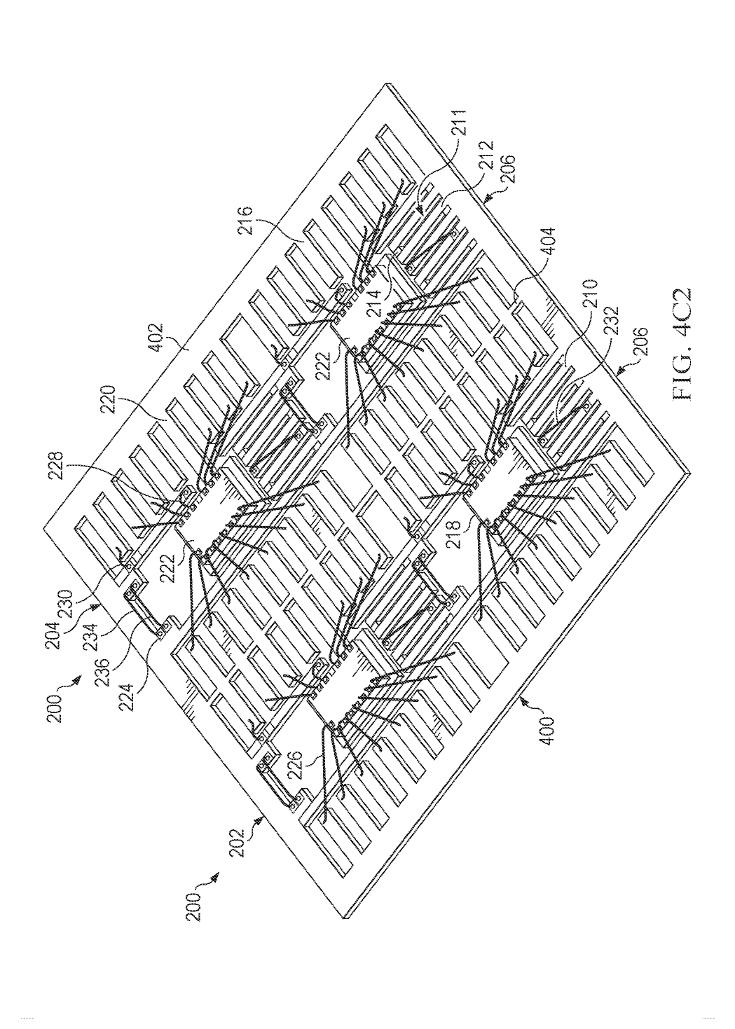

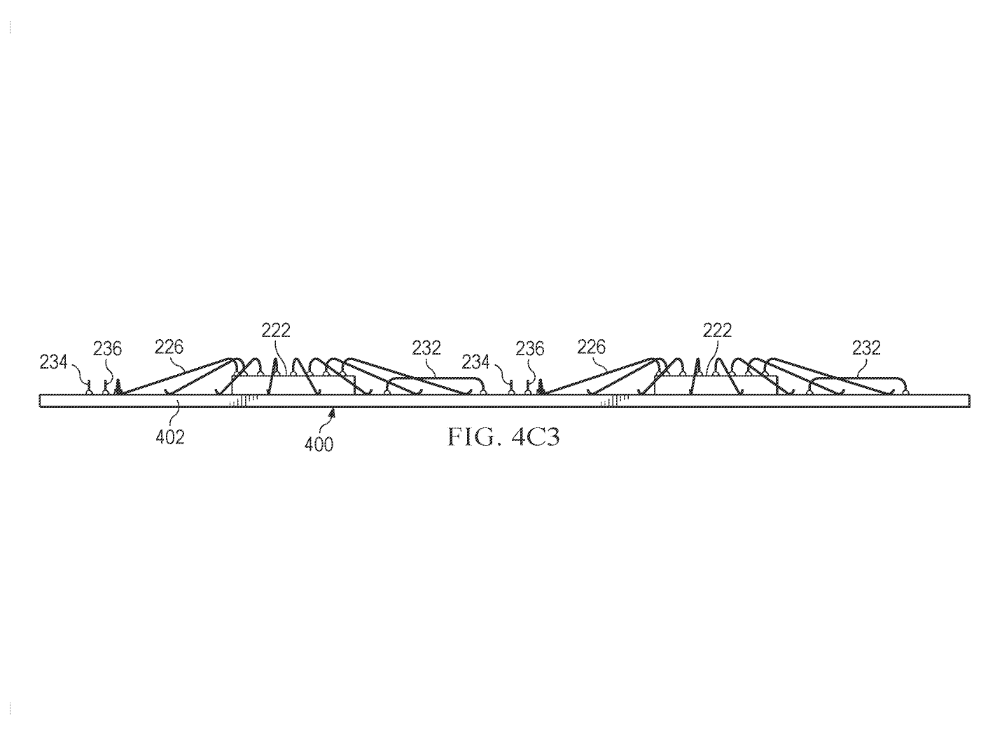

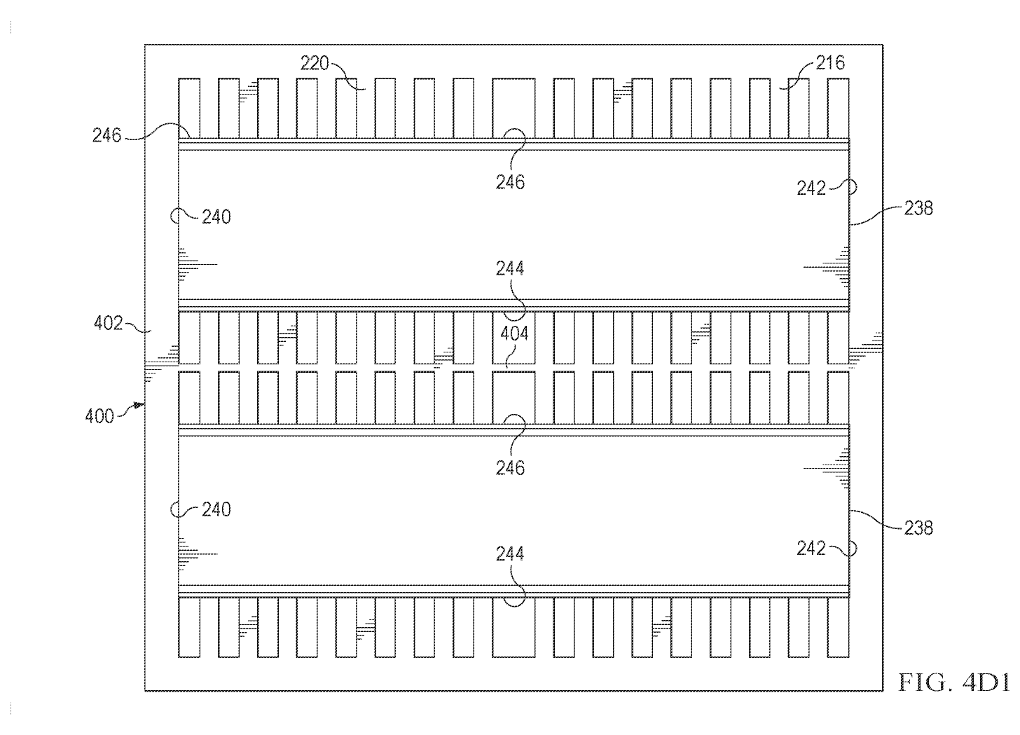

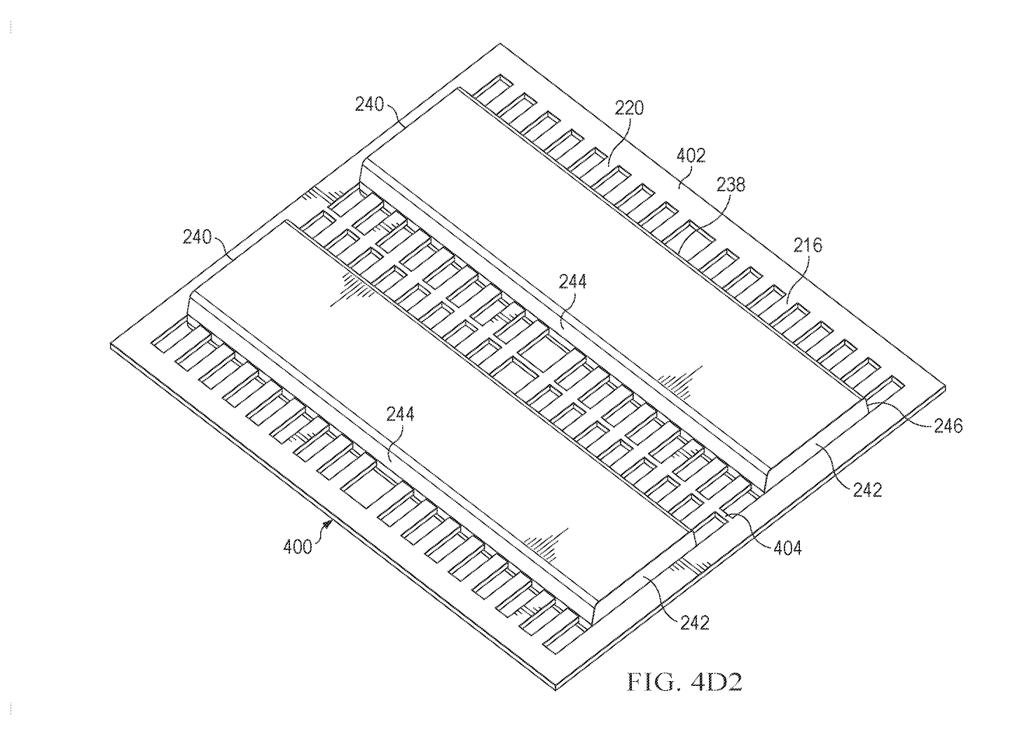

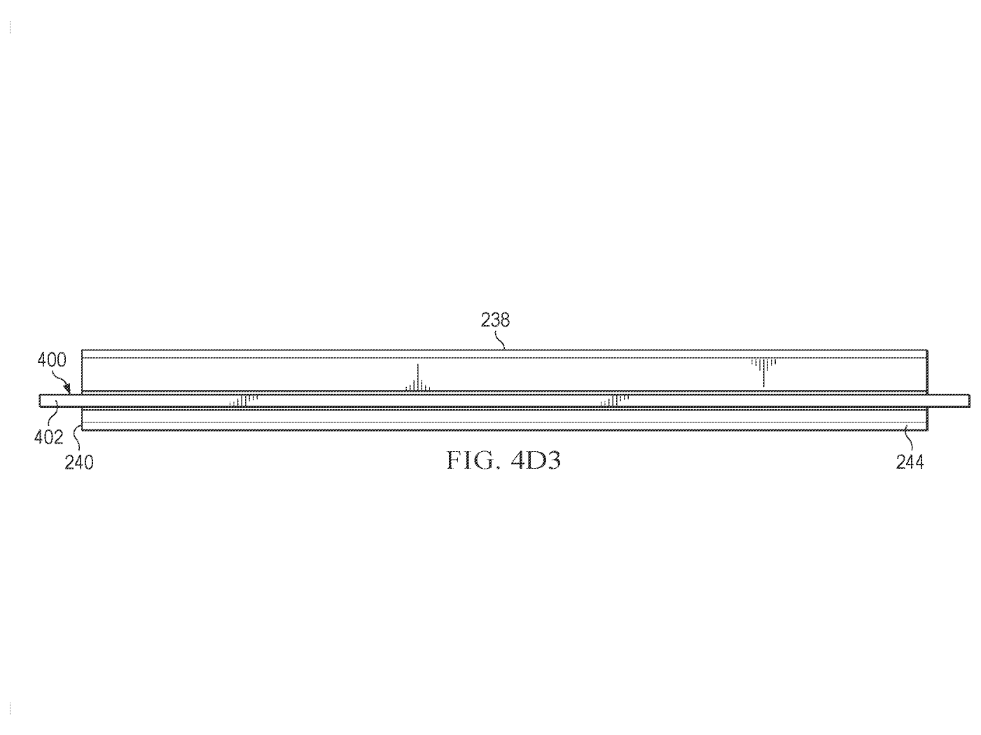

FIG. 3 is a flow diagram of a method 300 for manufacturing a semiconductor package having a lead frame antenna, in accordance with various examples. FIGS. 4A1,4A2, 4A3, 4B1, 4B2, 4B3, 4C1, 4C2, 4C3, 4D1, 4D2, and 4D3 are a process flow of a method for manufacturing a semiconductor package having a lead frame antenna, in accordance with various examples. Accordingly, FIGS. 3 and 4A1-4D3 are now described in parallel.

The method 300 may include obtaining a lead frame including a meander line antenna, a die pad, and a package pin (302).FIGS. 4A1, 4A2, and 4A3 are top-down, perspective, and profile views of a lead frame 400 including antennas 200 (e.g., meander line antennas 200), die pads 218, and package pins 216. The lead frame 400 includes a perimeter 402 and tie bars 404. The lead frame 400 also may include dam bars to control mold compound flow, but such dam bars are omitted from FIGS. 4A1-4A3 for clarity.

The method 300 may include coupling a semiconductor die to the die pad (304). FIGS. 4B1, 4B2, and 4B3 are top-down, perspective, and profile views of the structure of FIGS. 4A1-4A3, except that semiconductor dies 222 are coupled to the die pads 218, as shown. For example, the semiconductor dies 222 are coupled to the die pads 218 with a suitable die attach layer.

The method 300 may include coupling a first end of a bond wire to a device side of the semiconductor die and a second end of the bond wire to the meander line antenna (306).FIGS. 4C1, 4C2, and 4C3 are top-down, perspective, and profile views of the structure of FIGS. 4A1-4A3, except that the bond wires 226, 228, and 230 are coupled as shown in FIG. 2A and as described above.

The method 300 may include covering the semiconductor die, the bond wire, and at least a portion of the lead frame with a mold compound (308). FIGS. 4D1, 4D2 and 4D3 are top-down, perspective, and profile views of the structure of FIGS. 4C1-4C3, except that the mold compound 238 has been applied to the semiconductor dies 222, the bond wires 226, 228, and 230, and at least some of the lead frame 400, including the antennas 200.

The method 300 may include cutting the lead frame and the mold compound to produce the semiconductor package, where the meander line antenna is exposed on multiple external lateral surfaces of the mold compound after the cutting (310). The package pins may be formed (e.g., bent), and the tie bars 404 may be trimmed. The resulting structure is shown in FIGS. 2A-2D and described in detail above.

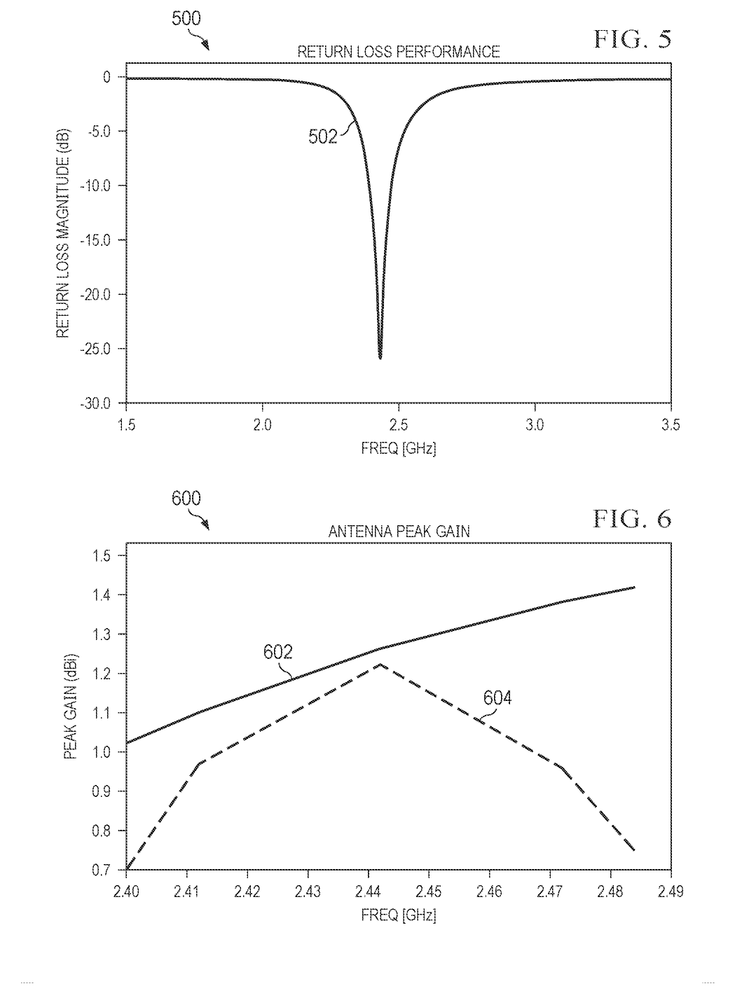

FIGS. 5, 6, and 7 are graphs depicting the performance of a semiconductor package having a lead frame antenna (e.g., the semiconductor package 104 including the antenna 200), in accordance with various examples. These graphs establish that a high-frequency, high-performance antenna can be effectively included in a semiconductor package (e.g., a small form factor, low-cost semiconductor package) by including the antenna as part of the lead frame used to manufacture the semiconductor package. In a graph 500 of FIG. 5, the x-axis represents frequency in GHz and the y-axis represents return loss magnitude in decibels (dB). A curve 502 indicates the return loss magnitude as a function of operating frequency for the antenna 200 in the semiconductor package 104. Specifically, the curve 502 depicts how effectively the antenna 200 reflects versus transmits radio frequency (RF) energy at various frequencies. The return loss magnitude indicates the proportion of energy reflected back, with higher negative values representing better energy absorption and transmission. At 2.4 GHz, a significant dip in return loss to -20.39 dB indicates that the antenna 200 is well-tuned to this frequency, minimizing reflected energy and maximizing efficiency in radiating or receiving signals.

FIG. 6 is a graph 600 illustrating antenna 200 peak gain, with frequency in GHz on the x-axis and peak gain in decibels relative to an isotropic radiator (dBi) on the y-axis. A curve 602 shows the theoretical directional gain of the antenna 200, increasing slightly from 1.02dBi at 2.4 GHz to 1.42 dBi at 2.485 GHz, indicating consistent directional focus across this frequency range. A curve 604 reflects the actual directional performance when accounting for losses such as impedance mismatches. The curve 604 starts at 0.70 dBi at 2.4 GHz, peaks at 1.22 dBi near 2.442 GHz, and decreases to 0.75 dBi at 2.484 GHz. The peak at 2.442 GHz indicates optimal real-world performance, aligning with the target operational frequency of the antenna 200.

FIG. 7 is a graph 700 illustrating antenna 200 radiation efficiency. The graph 700 illustrates the radiation efficiency of the antenna 200 as a function of frequency, with the x-axis representing frequency in gigahertz (GHz) and the y-axis indicating the efficiency metric scaled by a factor of 100, denoted as "Radiation Efficiency × 100." Radiation efficiency is a measure of how effectively an antenna converts the input power into radiated electromagnetic energy, expressed as a percentage. By multiplying the efficiency by 100, the y-axis values provide the efficiency in its percentage form without requiring further conversion. The curve 702 indicates that the antenna 200 has a radiation efficiency that varies slightly across the frequency range of 2.4 GHz to 2.484 GHz, starting at 59.71% and increasing to 65.25%. This relatively stable and high-efficiency range indicates consistent performance of the antenna 200 across the specified frequencies, making the antenna 200 suitable for applications within this band.

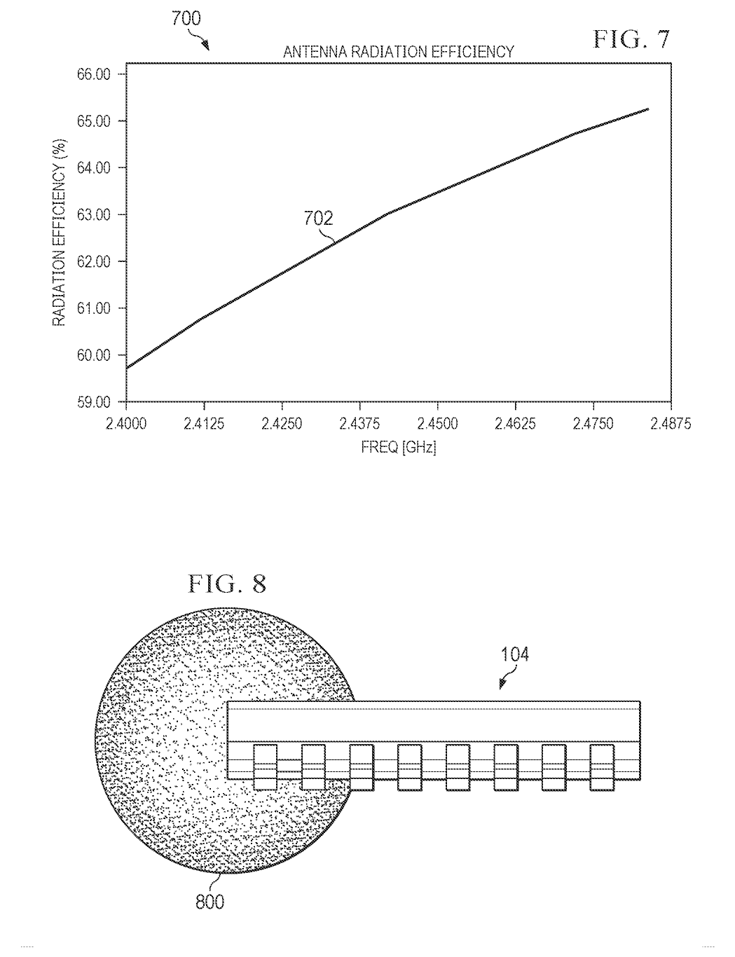

FIG. 8 is a schematic diagram depicting the radiation pattern of a semiconductor package having a lead frame antenna, in accordance with various examples. Specifically, FIG. 8 shows the semiconductor package 104 and a radiation pattern 800 of the antenna 200. As shown, the radiation pattern 800 is substantially symmetrical, establishing that desirable radiation patterns can be achieved by lead frame antennas, such as the antenna 200 described herein.

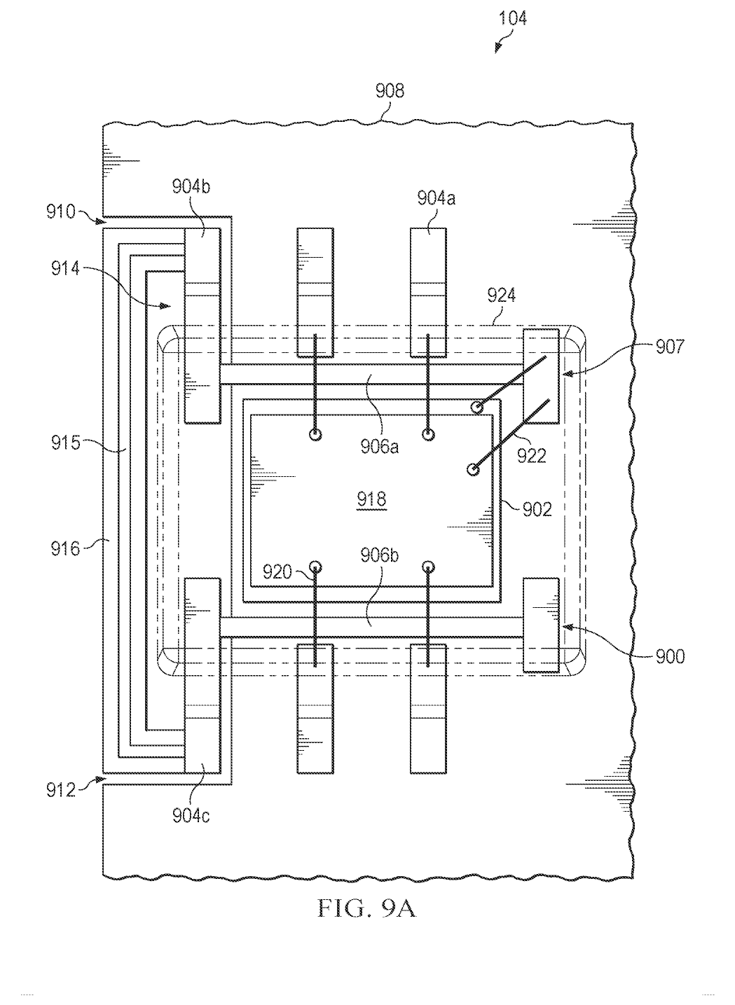

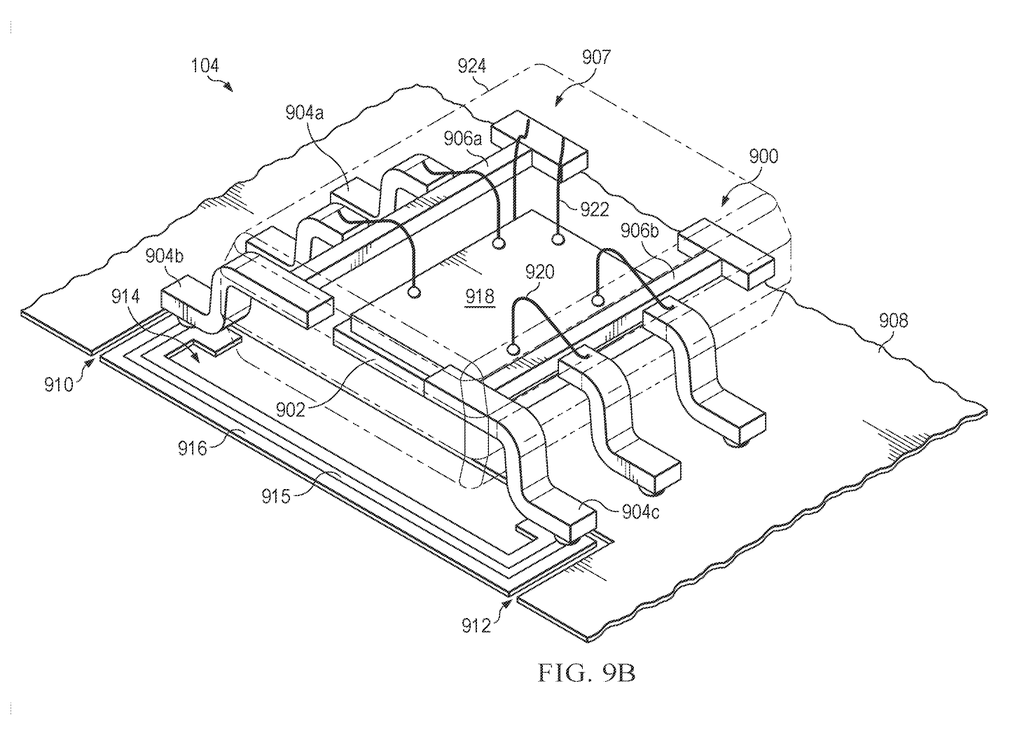

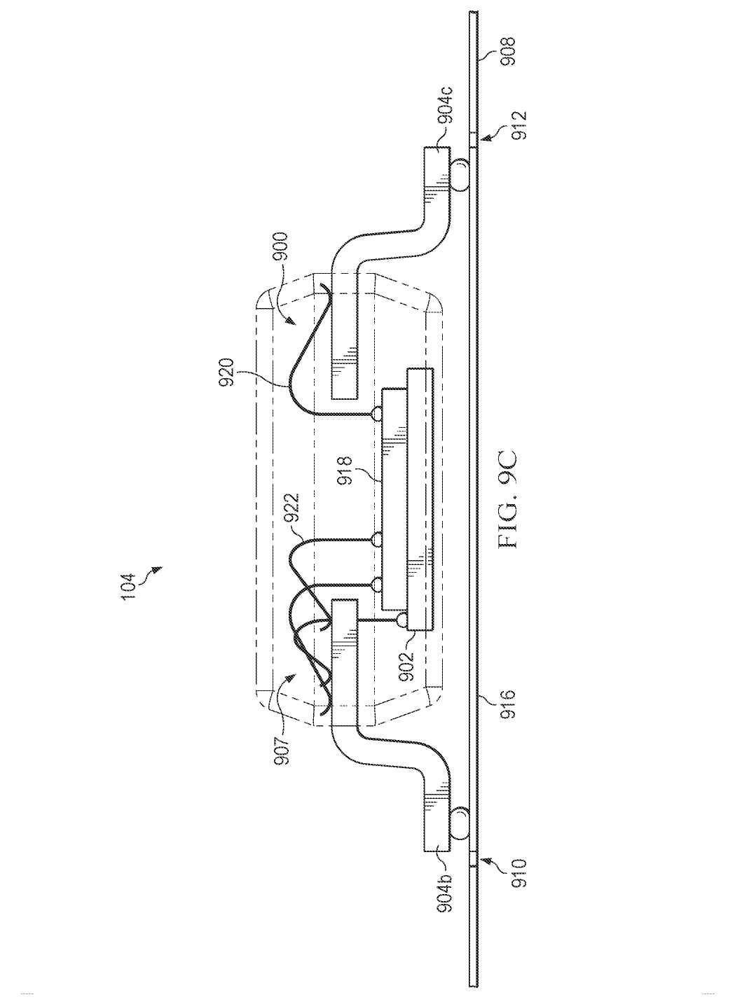

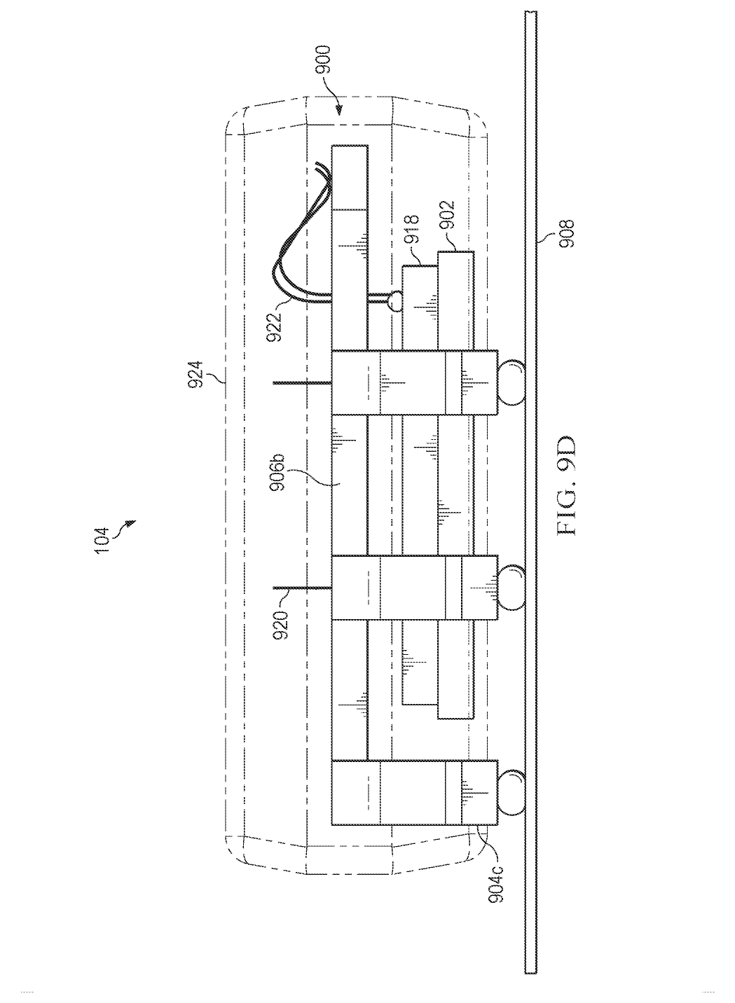

In some examples, a lead frame antenna may include segments of a lead frame and segments of a PCB, such as the PCB on which the semiconductor package that includes the lead frame antenna is mounted. FIGS. 9A, 9B, 9C, and 9D are top-down, perspective, profile, and profile views of a semiconductor package including a lead frame antenna, in accordance with various examples. The example package 104 includes a portion of a lead frame 900, which includes a die pad 902, package pins 904 (e.g., 904a, 904b, and 904c), and antenna segments 906 (e.g., 906a and 906b) forming an antenna 907. The semiconductor package 104 is coupled to a PCB 908 (e.g., by solder joints). The PCB 908 includes openings 910, 912, and 914 that are in communication with each other, as shown. Consequently, a PCB segment 916 is physically separate from the remainder of the PCB 908. Package pin 904b is coupled to antenna segment 906a, or alternatively, package pin 904b and antenna segment 906a form a monolithic whole (i.e., they are part of a lead frame used to manufacture the semiconductor package 104). Similarly, package pin 904c is coupled to antenna segment 906b, or alternatively, package pin 904c and antenna segment 906b form a monolithic whole. The package pins 904b and 904c couple to a metal trace 915 that is present on the PCB segment 916. A semiconductor die 918 having a device side in which circuitry is formed is coupled to the die pad 902, with the device side facing away from the die pad 902. Bond wires 920 couple the device side of the semiconductor die 918 to package pins 904, and a bond wire 922 couples the device side of the semiconductor die 918 to the antenna 907, as shown. A mold compound 924 covers the various structures of the package 104. In operation, the semiconductor die 918 provides signals to and receives signals from the antenna 907, which includes the antenna segment 906a, the package pin 904b, the metal trace 915, the package pin 904c, and the antenna segment 906b.

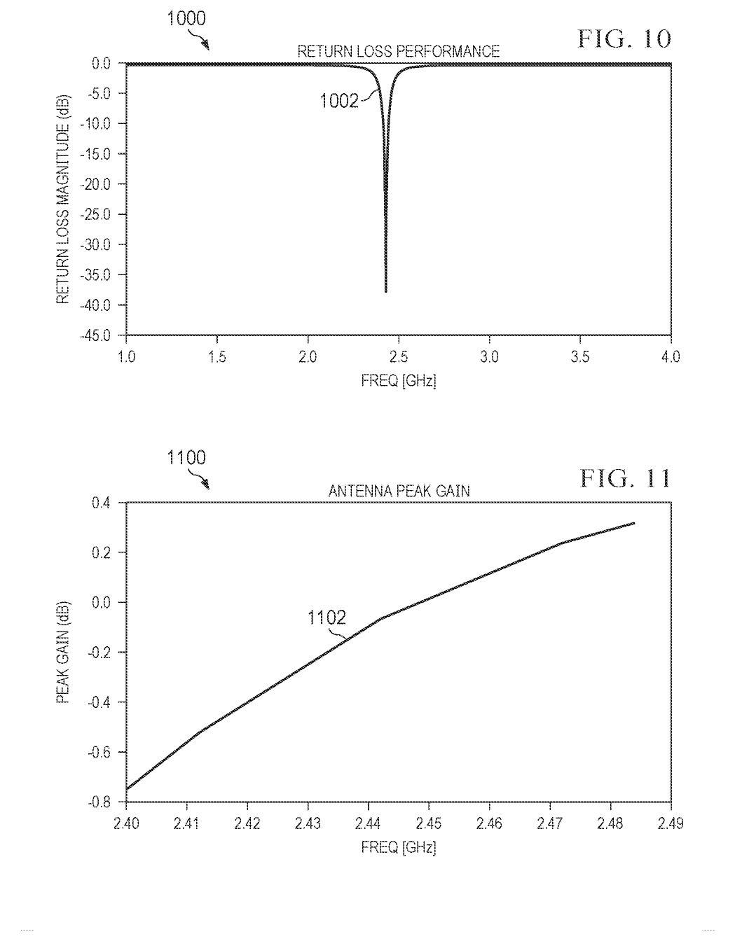

FIGS. 10, 11, and 12 are graphs depicting the performance of a semiconductor package having a lead frame antenna, in accordance with various examples. These graphs establish that a high-frequency, high-performance antenna, such as the antenna 907 in FIGS. 9A-9D, can be effectively included in a semiconductor package (e.g., a small form factor, low-cost semiconductor package) by including portions of the antenna 907 as part of the lead frame used to manufacture the semiconductor package. In a graph 1000 of FIG. 10, the x-axis represents frequency in GHz and the y-axis represents return loss magnitude in decibels (dB). A curve 1002 indicates the return loss magnitude as a function of operating frequency for the antenna 907 in the semiconductor package 104. Specifically, the curve 1002 depicts how effectively the antenna 907 reflects versus transmits radio frequency (RF) energy at various frequencies. The return loss magnitude indicates the proportion of energy reflected back, with higher negative values representing better energy absorption and transmission. At approximately 2.4 GHz, a significant dip in return loss to -42 dB indicates that the antenna 907 is well-tuned to this frequency, minimizing reflected energy and maximizing efficiency in radiating or receiving signals.

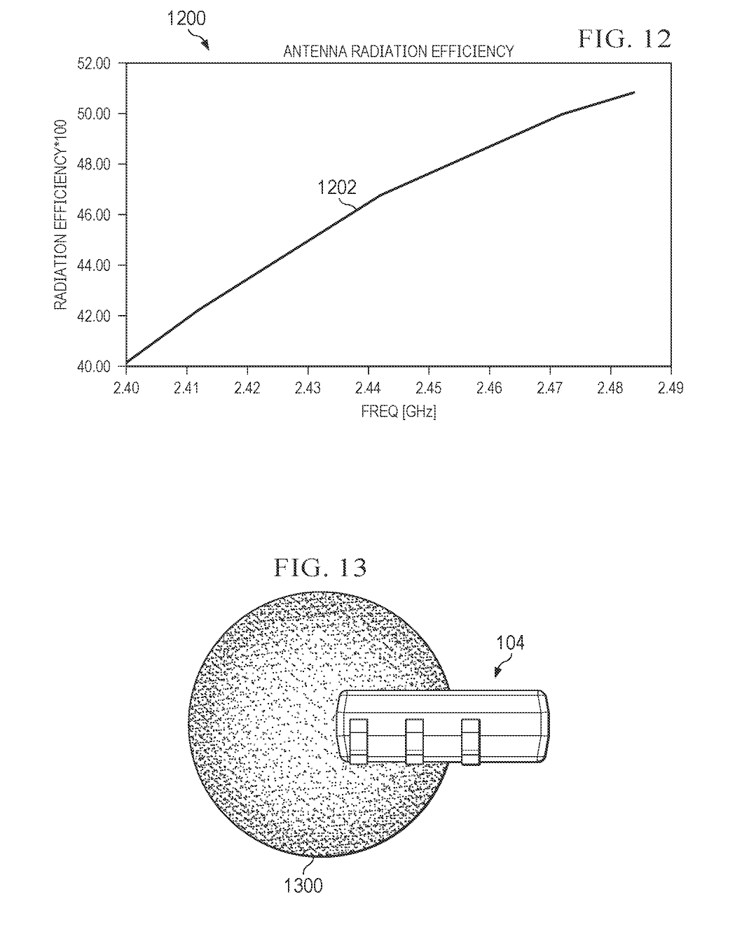

FIG. 11 is a graph 1100 illustrating antenna 907 peak gain, with frequency in GHz on the x-axis and peak gain in decibels (dB) on the y-axis. A curve 1102 shows the peak gain of the antenna 907, increasing from -0.76 dB at 2.4 GHz to 0.32 dB at 2.484 GHz. FIG. 12 is a graph 1200 illustrating antenna 907 radiation efficiency. The graph 1200 illustrates the radiation efficiency of the antenna 907 as a function of frequency, with the x-axis representing frequency in gigahertz (GHz) and the y-axis indicating the efficiency metric scaled by a factor of 100, denoted as "Radiation Efficiency × 100." Radiation efficiency is a measure of how effectively an antenna converts the input power into radiated electromagnetic energy, expressed as a percentage. By multiplying the efficiency by 100, the y-axis values provide the efficiency in its percentage form without requiring further conversion. The curve 1202 indicates that the antenna 907 has a radiation efficiency that varies slightly across the frequency range of 2.4 GHz to 2.484 GHz, starting at 40.40% and increasing to 50.80%. This relatively stable and high-efficiency range indicates consistent performance of the antenna 907 across the specified frequencies, making the antenna 907 suitable for applications within this band.

FIG. 13 is a schematic diagram depicting the radiation pattern of a semiconductor package having a lead frame antenna, in accordance with various examples. Specifically, FIG. 13 shows the semiconductor package 104 and a radiation pattern 1300 of the antenna 907. As shown, the radiation pattern 1300 is substantially symmetrical, establishing that desirable radiation patterns can be achieved by lead frame antennas, such as the antenna 907 described herein.

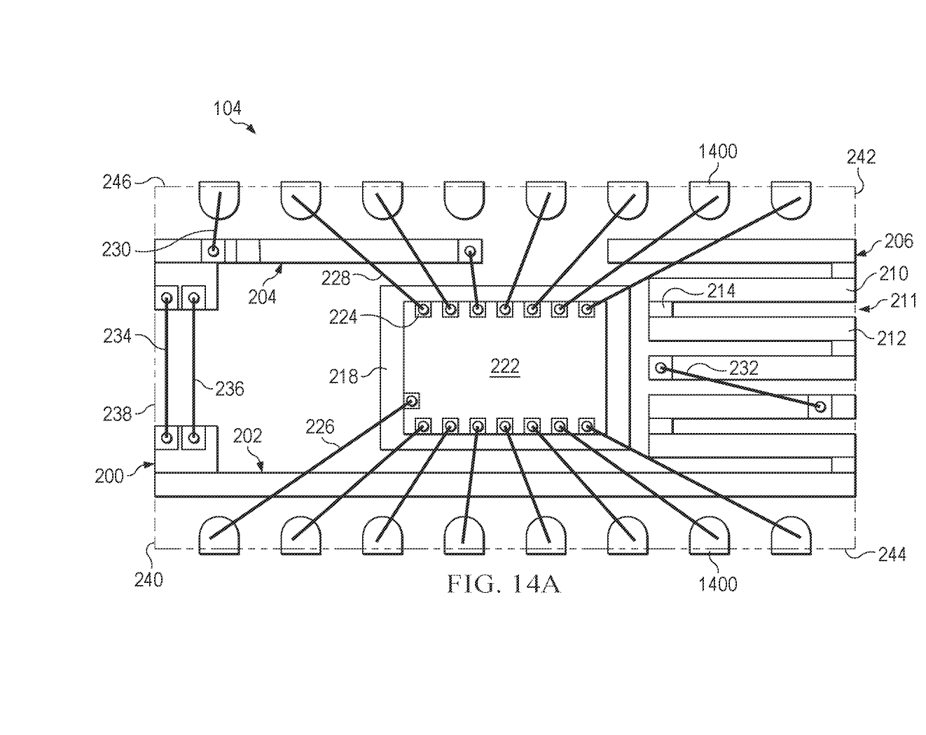

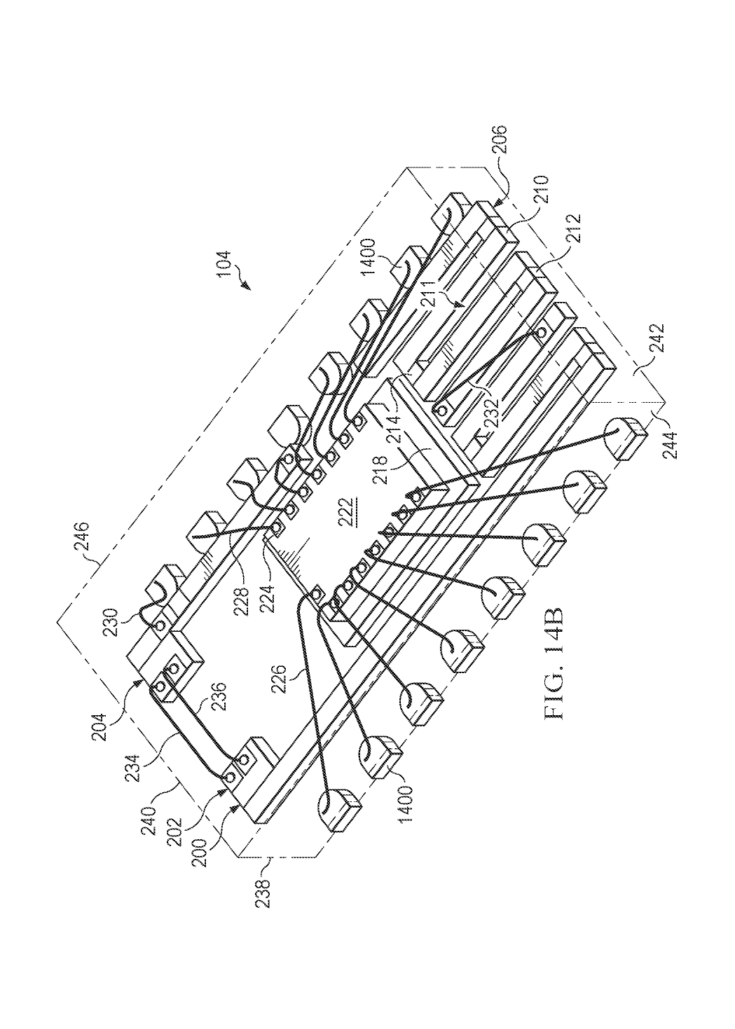

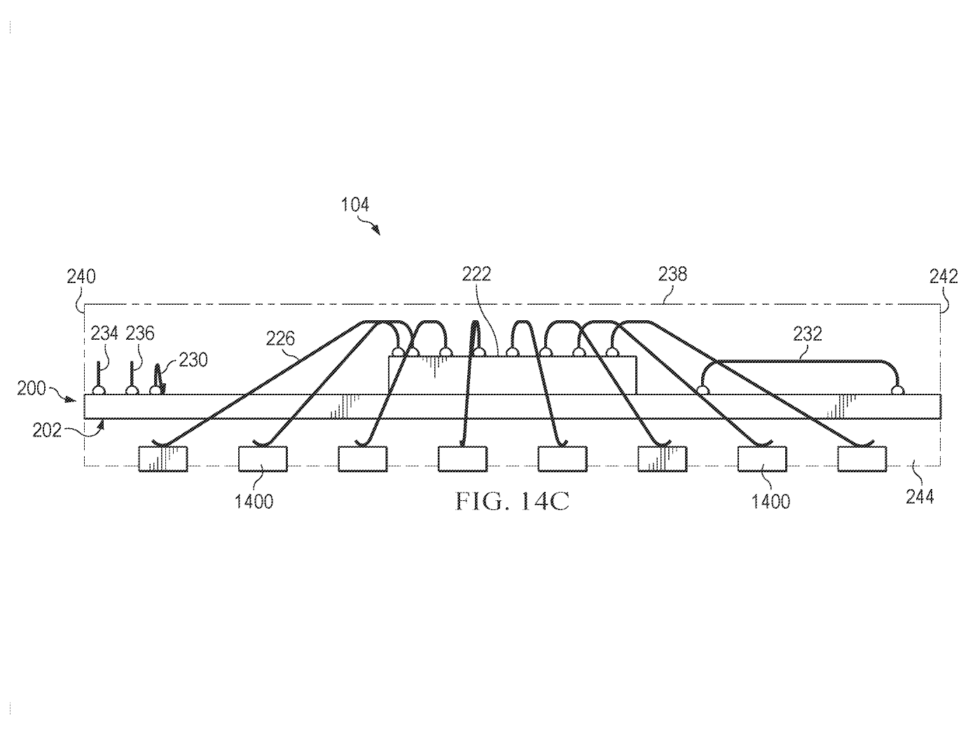

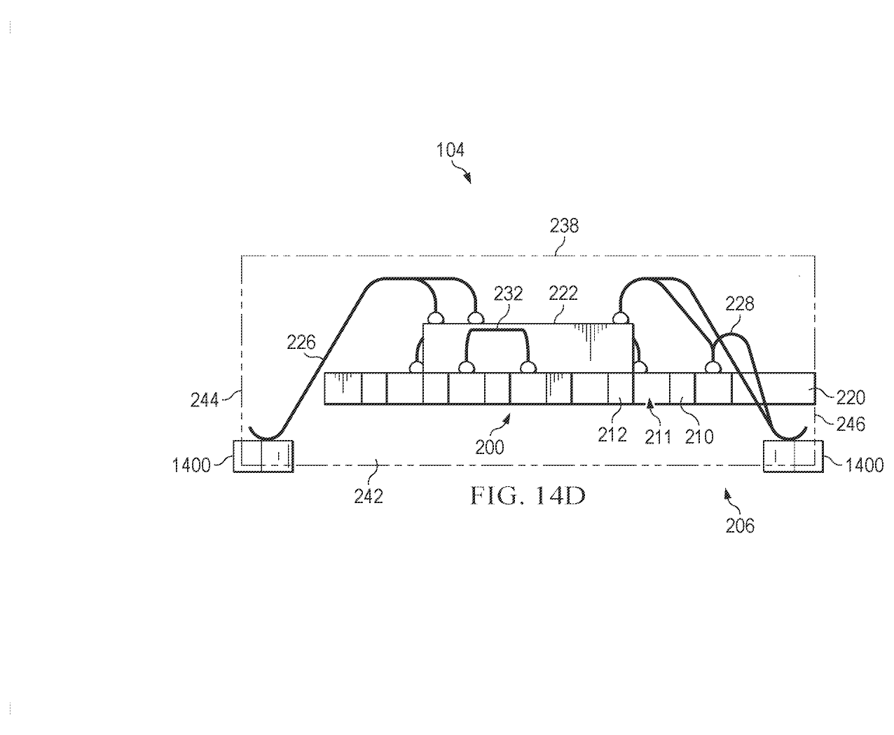

Some of the packages described above are of particular types. Other types of packages are contemplated and included in the scope of this disclosure. Examples of such packages include quad flat no lead (QFN) packages and dual flat no lead (DFN) packages. FIGS. 14A, 14B, 14C, and 14D are top-down, perspective, profile, and profile views of a semiconductor package having a lead frame antenna, in accordance with various examples. Specifically, FIGS. 14A-14D depict a DFN package 104 having package pins 1400 in the pattern shown. The structure of the DFN package 104 shown in FIGS. 14A-14D is identical to that of the example package 104 in FIGS. 2A-2D, except that the package pins 1400 are flat, no-lead style pins.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

In this description, unless otherwise stated, “about,” “approximately” or “substantially” preceding a parameter means being within +/- 10 percent of that parameter. Modifications are possible in the described examples, and other examples are possible within the scope of the claims.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device, or a semiconductor component.

What is claimed is:

1. A semiconductor package, comprising:
a portion of a lead frame including a die pad, a package pin, and an antenna having first and second segments, at least one of the first and second segments having a meandering portion;
a semiconductor die coupled to the die pad and having a device side in which circuitry is formed;
a first bond wire coupling the device side to the package pin;
a second bond wire coupling the first segment to the second segment;
a third bond wire coupling the device side to the antenna; and
a mold compound covering the semiconductor die, at least part of the package pin, the antenna, and the first, second, and third bond wires, portions ofthe first and second segments exposed on multiple exterior lateral surfaces of the mold compound.

2. The semiconductor package of claim 1, wherein the semiconductor package is configured to operate at a frequency of approximately 2.4 GHz.

3. The semiconductor package of claim 1, further comprising a fourth bond wire coupled to the antenna and to the package pin.

4. The semiconductor package of claim 1, wherein the antenna and the package pin form a monolithic structure and are not fused to each other.

5. The semiconductor package of claim 1, wherein the multiple exterior lateral surfaces oppose each other.

6. The semiconductor package of claim 1, wherein the multiple exterior lateral surfaces are perpendicular to another exterior lateral surface that has a larger surface area than each of the multiple exterior lateral surfaces.

7. The semiconductor package of claim 1, further comprising a fourth bond wire coupling the first segment to the second segment, the fourth bond wire extending approximately parallel to the second bond wire.

8. The semiconductor package of claim 1, wherein a top surface of the die pad is coplanar with top surfaces of the first and second segments of the antenna, and wherein the semiconductor package is one of a small outline transistor (SOT) package and a dual flat no lead (DFN) package.

9. A semiconductor package, comprising:
a portion of a lead frame including a die pad, a package pin, and an antenna having a meandering portion that includes multiple linear segments linked in series at approximately right angles, each of the multiple linear segments at least partially separated from another one of the multiple linear segments by a non-metallic region;
a semiconductor die coupled to the die pad, the package pin, and the antenna; and
a mold compound covering the portion of the lead frame and the semiconductor die.

10. The semiconductor package of claim 9, wherein the antenna and the package pin form a monolithic structure and have not been fused together.

11. The semiconductor package of claim 9, further comprising a pair of bond wires coupling first and second linear segments of the multiple linear segments.

12. The semiconductor package of claim 11, wherein the pair of bond wires are approximately in parallel with each other.

13. The semiconductor package of claim 9, further comprising a tie bar coupled to the die pad and exposed on an external surface of the mold compound.

14. The semiconductor package of claim 9, wherein the semiconductor package is a small outline transistor (SOT) package or a dual flat no lead (DFN) package.

15. The semiconductor package of claim 9, wherein the semiconductor package is configured to operate at a frequency of approximately 2.4 GHz.

16. A method for manufacturing a semiconductor package, comprising:
coupling a first semiconductor die to a first die pad of a lead frame, the lead frame further comprising a second die pad, first and second package pins, and first and second antennas, the first and second antennas coupled directly to each other without a tie bar in between the first and second antennas, each of the first and second antennas including multiple linear segments coupled in series at approximately right angles;
coupling a second semiconductor die to the second die pad;
wirebonding the first semiconductor die to the first package pin and the first antenna;
wirebonding the second semiconductor die to the second package pin and the second antenna;
covering the first and second semiconductor dies, the first and second die pads, and the first and second antennas with a mold compound; and
cutting the mold compound and the lead frame in between the first and second antennas to produce the semiconductor package.

17. The method of claim 16, wherein the mold compound is present between the multiple linear segments of the first antenna.

18. The method of claim 16, wherein the first antenna is exposed on multiple external surfaces of the semiconductor package.

19. The method of claim 18, wherein the multiple external surfaces are opposite each other and have smaller surface areas than other external surfaces that are perpendicular to the multiple external surfaces.

20. The method of claim 16, wherein a tie bar coupled to the first die pad is exposed on an external surface of the semiconductor package.
